(19) United States
(12) Patent Application Publication
(10) Pub. No.: US 2020/0081568 A1
(43) Pub. Date: Mar. 12, 2020

(54) DISPLAY PANEL AND DISPLAY DEVICE

(71) Applicant: WuHan TianMa Micro-Electronics Co., Ltd., Wuhan (CN)

(72) Inventors: Ning XU, Wuhan (CN); Jingxiong ZHOU, Wuhan (CN); Ruiyuan ZHOU, Wuhan (CN)

(21) Appl. No.: 16/257,118

(22) Filed: Jan. 25, 2019

(30) Foreign Application Priority Data
Sep. 10, 2018 (CN) 201811049426.0

(51) Int. Cl. G06F 3/041; G06F 3/044; G06F 3/047; G02F 1/1333; G02F 1/1362; H01L 27/32

(52) U.S. Cl. CPC G06F 3/0412; G06F 3/044; G06F 3/047; H01L 27/323; G02F 1/136286; H01L 27/3276; G02F 1/13338

(57) ABSTRACT

The present disclosure provides a display panel and a display device. The display panel and display device include a first substrate and a second substrate positioned opposite the first substrate. The first substrate includes first binding pin, and the second substrate includes second binding pin. The second substrate further includes at least one protruding portion and at least one recessed portion, the second binding pins are located on the protruding portion, and the first binding pins are exposed from the recessed portion. Such configuration reduces a total width of a binding region of the display panel and the display device, achieves a narrow border, and improves a display area occupation ratio.

### CROSS-REFERENCE TO RELATED APPLICATIONS

The present application claims priority to Chinese Patent Application No. 201811049426.0, filed on Sep. 10, 2018, the content of which is incorporated herein by reference in its entirety.

### TECHNICAL FIELD

The present disclosure relates to the display field, and in particular, to a display panel and a display device.

### BACKGROUND

In the existing display device techniques, the display panel is mainly classified into two prevalent techniques, i.e., liquid crystal display panels and organic light-emitting display panels. The liquid crystal display panel generates, by exerting a voltage on a pixel electrode and a common electrode, an electric field capable of controlling deflection of liquid crystal molecules, thereby controlling transmission of light and realizing display function of the liquid crystal display panel; the organic light-emitting display panel adopts an organic electroluminescent material, and when a current passes through the organic electroluminescent material, the organic electroluminescent material will emit light, thereby realizing the display function of the organic light-emitting display panel.

With the application of display technology in smart wearable devices and other portable electronic devices, users are increasingly pursuing higher screen resolution, thinner and lighter device body, higher display area ratio, and richer functions for electronic products.

In the existing design, since it is necessary to provide a display signal to the display component of the display panel, it is necessary to set a binding area for connecting a chip or a power supply device on the display panel. Further, because of a wide application of integrated touch, it is also necessary to provide a binding area of touch signals on the display panel for connecting the touch chip, for processing the touch signals and recognizing a touch position. More functional settings and higher screen resolution require a larger border area, and thus a display device is needed in the field that can take into account the user's requirements on higher display area ratio and higher performance.

### SUMMARY

The present disclosure provides a display panel, which can meet the needs of the user in reducing the width of the border and increasing the area ratio of the display area while achieving high-resolution display and integrated touch.

The present disclosure provides a display panel including a first substrate including a plurality of first binding pins; and a second substrate arranged opposite to the first substrate. The second substrate includes a plurality of second binding pins, at least one protruding portion, and at least one recessed portion. The plurality of second binding pins is located on the at least one protruding portion of the second substrate, and the plurality of first binding pins of the first substrate is exposed from the at least one recessed portion of the second substrate.

The present disclosure further provides a display device including any display panel of the present disclosure.

### BRIEF DESCRIPTION OF THE DRAWINGS

In order to illustrate embodiments of the present disclosure or the technical solutions in the related art, a brief introduction will be made to the accompany drawings required in the description of the embodiments or the prior art. The drawings in the following description merely involve some embodiments of the present disclosure, and those skilled in the art can obtain other drawings according to these drawings without paying any creative work.

FIG. 1 is a top view of a display panel according to an embodiment of the present disclosure.

FIG. 2 is an exploded view of the display panel shown in FIG. 1.

FIG. 3A is a schematic diagram of a display panel of the prior art.

FIG. 3B is a schematic diagram of a display panel according to an embodiment of the present disclosure.

FIG. 4 is a top view of another display panel according to an embodiment of the present disclosure.

FIG. 5 is an exploded view of the display panel shown in FIG. 4.

FIG. 6 is a top view of another display panel according to an embodiment of the present disclosure.

FIG. 7 is a top view of another display panel according to an embodiment of the present disclosure.

FIG. 8 is a top view of another display panel according to an embodiment of the present disclosure.

FIG. 9 is a top view of another display panel according to an embodiment of the present disclosure.

FIG. 10 is a top view of another display panel according to an embodiment of the present disclosure.

FIG. 11 is a top view of another display panel according to an embodiment of the present disclosure.

FIG. 12 is a top view of another display panel according to an embodiment of the present disclosure.

FIG. 13 is a top view of another display panel according to an embodiment of the present disclosure.

FIG. 14 is an exploded view of another display panel according to an embodiment of the present disclosure.

FIG. 15 is a side view of a display panel according to an embodiment of the present disclosure.

FIG. 16 is a side view of another display panel according to an embodiment of the present disclosure.

FIG. 17 is an exploded view of another display panel according to an embodiment of the present disclosure.

FIG. 18 is a top view of a display device according to an embodiment of the present disclosure.

### DESCRIPTION OF EMBODIMENTS

In order to make the objectives, technical solutions, and advantages of the embodiments of the present disclosure more clear, the technical solutions in the embodiments of the present disclosure are described in detail in conjunction with the accompanying drawings. The described embodiments are only a part of the embodiments of the present disclosure, rather than all of the embodiments. Based on the described embodiments of the present disclosure, all other embodiments obtained by those skilled in the art without creative efforts are within the protection scope of the present disclosure.

The terms used in the embodiments of the present disclosure are merely for the purpose of describing particular embodiments, and are not intended to limit the disclosure. The words “a”, “an”, “the” and “said” in a singular form are also intended to include plural forms thereof, unless the context clearly indicates otherwise.

It should be understood that the term “and/or” as used herein is merely an association describing the associated objects, indicating that there may be three relationships, for example, “A and/or B” may represent: only A exists, both A and B exist, and only B exists. In addition, the character “/” as used herein generally indicates an “or” relation.

Although terms “first”, “second”, “third” are used to describe substrates, binding pins, flexible circuit boards, lead lines, chips, touch lead lines, protruding portions, recessed portions, etc., the substrates, binding pins, flexible circuit boards, lead lines, chips, touch lead lines, protruding portions, and recessed portions are not limited by those terms. These terms are merely used to distinguishing the substrates, binding pins, flexible circuit boards, lead lines, chips, touch lead lines, protruding portions, or recessed portions from one another. For example, without departing from the protection scope of the present disclosure, a first substrate, binding pin, flexible circuit board, lead line, chip, touch lead line, protruding portion, or recessed portion may be referred to as a second substrate, binding pin, flexible circuit board, lead line, chip, touch lead line, protruding portion, or recessed portion. Similarly, a second substrate, binding pin, flexible circuit board, lead line, chip, touch lead line, protruding portion, or recessed portion may also be referred to as a first substrate, binding pin, flexible circuit board, lead line, chip, touch lead line, protruding portion, or recessed portion.

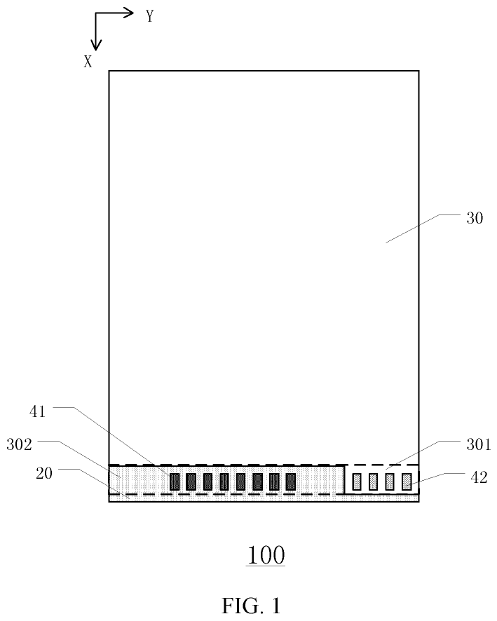

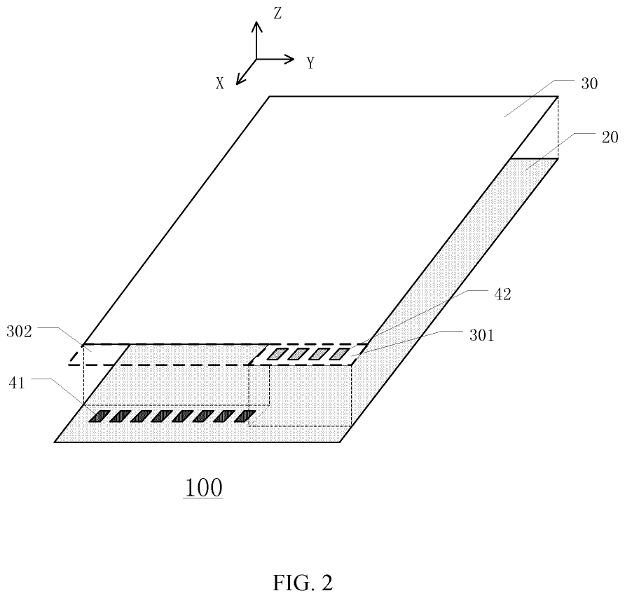

An embodiment of the present disclosure provides a display panel 100, as shown in FIG. 1 and FIG. 2, including a first substrate 20 and a second substrate 30. The second substrate 30 is positioned opposite the first substrate 20. The first substrate 20 includes a plurality of first binding pins 41 arranged thereon, and the second substrate 30 includes a plurality of second binding pins 42 arranged thereon.

Further referring to FIG. 1 and FIG. 2, the second substrate 30 further includes at least one protruding portion 301 and at least one recessed portion 302. The plurality of second binding pins 42 are positioned at the at least one protruding portion 301 of the second substrate 30. That is, the plurality of second binding pins 42 are positioned on the at least one protruding portion 301 of the second substrate 30. The at least one recessed portion 302 of the second substrate 30 exposes the plurality of first binding pins 41 of the first substrate 20. That is, the at least one recessed portion 302 of the second substrate 30 overlaps the plurality of first binding pins 41 of the first substrate 20 in a direction perpendicular to the display panel 100, such that the at least one recessed portion 302 of the second substrate 30 can expose the plurality of first binding pins 41 of the first substrate 20, thereby facilitating binding. In other words, the second substrate 30 does not cover the plurality of first binding pins 41 of the first substrate 20. The direction perpendicular to the display panel 100 is referred to as a third direction Z.

According to the display panel 100 provided by this embodiment, the second substrate 30 is provided with the protruding portion 301 and the recessed portion 302, and the second binding pins 42 are arranged on the protruding portion 301, and the first binding pins 41 are exposed from the recessed portion 302. Accordingly, the first binding pins 41 partially overlap the second binding pins 42 in a second direction Y of display panel 100, i.e., a projection of the first binding pins 41 in the second direction Y overlaps a projection of the second binding pins 42 in the second direction Y, thereby reducing a width of the display panel 100 in a first direction X. In the display panel 100 of this embodiment, the first binding pins 41 perfectly avoid the second binding pins 42 in the direction perpendicular to the display panel (the third direction Z), but overlap the second binding pins 42 in the second direction Y, thereby reducing a total width of a binding region of the display panel 100, realizing a narrow border, and increasing an occupation ratio of the display region.

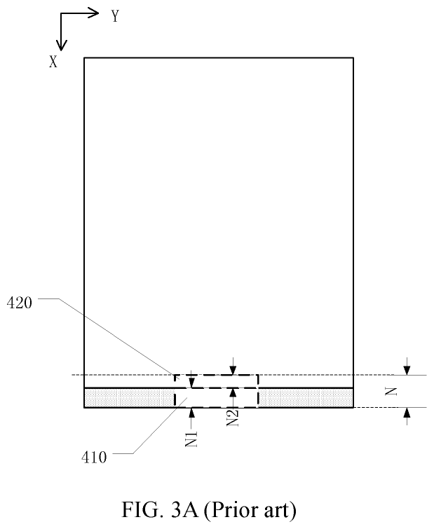

In order to directly show the advantages of the display panel 100 of this embodiment, FIG. 3A illustrates a diagram of the display panel according to the related art in which an edge of the second substrate 30 is parallel to an edge of the first substrate 20, the second substrate 30 has an even edge without the protruding portion and recessed portion; FIG. 3B illustrates another diagram of the display panel 100 of this embodiment according to the present disclosure.

Referring to FIG. 3A, the first binding region 410 where the first binding pins are located has a width of N1 in the first direction X, and the second binding region 420 where the second binding pins are located has a width of N2 in the first direction X. The non-display region including the first binding region 410 and the second binding region 420 has a width of N in the first direction X. It can be clearly seen from FIG. 3A that, a sum of N1 and N2 is equal to N.

Referring to FIG. 3B, the first binding region 410 where the first binding pins are located has a width of N1 in the first direction X, the second binding region 420 where the second binding pins are located has a width of N2 in the first direction X. The non-display region containing the first binding region 410 and the second binding region 420 has a width of N in the first direction X. It can be clearly seen from FIG. 3B that N is equal to N1, and a sum of N1 and N2 is greater than N.

Thus, by comparing FIG. 3A and FIG. 3B, it can be seen that the display panel 100 provided by the embodiment of the present disclosure has a narrower border and a higher occupation ratio of the display region.

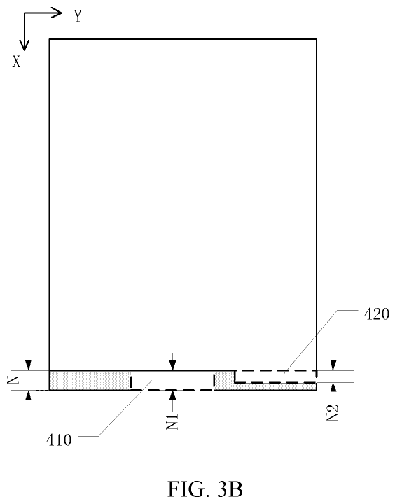

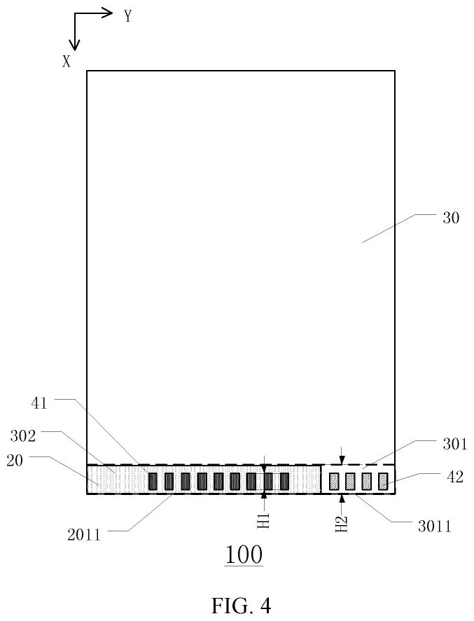

An embodiment of the present disclosure provide another display panel 100. As shown in FIG. 4 and FIG. 5, a part of a first edge 2011 of the first substrate 20 overlaps a first edge 3011 of the protruding portion 301 of the second substrate 30. That is, the part of the first edge 2011 of the first substrate 20 has a projection in the direction perpendicular to the display panel 100 overlapping a projection of first edge 3011 of the protruding portion 301 of the second substrate 30 in the direction perpendicular to the display panel 100 (the third direction Z). In other words, when viewed from top to bottom, in a top view direction of the display panel 100 (the third direction Z), a part of a first edge 2011 of the first substrate 20 coincides with a first edge 3011 of the protruding portion 301 of the second substrate 30, and in a side view direction of the display panel 100 (the first direction X), the part of a first edge 2011 of the first substrate 20 is even with the first edge 3011 of the protruding portion 301 of the second substrate 30.

In the display panel 100 of the present disclosure, the part of the first edge 2011 of the first substrate 20 coincides with the first edge 3011 of the protruding portion 301 of the second substrate 30 in such a manner that the border region of the display panel 100 can be effectively used to place the binding pins, and further reduce the width of the border of the display panel 100. It should be noted that, in FIG. 4, a second edge adjoining to the first edge 3011 of the protruding portion 301 of the second substrate 30 also coincides with a second edge adjoining to the first edge 2011 of the first substrate 20, so as to reduce a width of a side border of the display panel 100, and further increase the occupation ratio of the display area in the display panel 100.

Further referring to FIG. 4, the recessed portion 302 of the second substrate 30 has a length H2 in the first direction X greater than or equal to a length H1 of the first binding pins 41 in first direction X. That is, the recessed portion 302 of the second substrate 30 can completely expose the first binding pins 41 positioned on the first substrate 20 in the first direction X, thereby facilitating binding between the first binding pins 41 and the flexible circuit board or the chip, etc., increasing binding reliability.

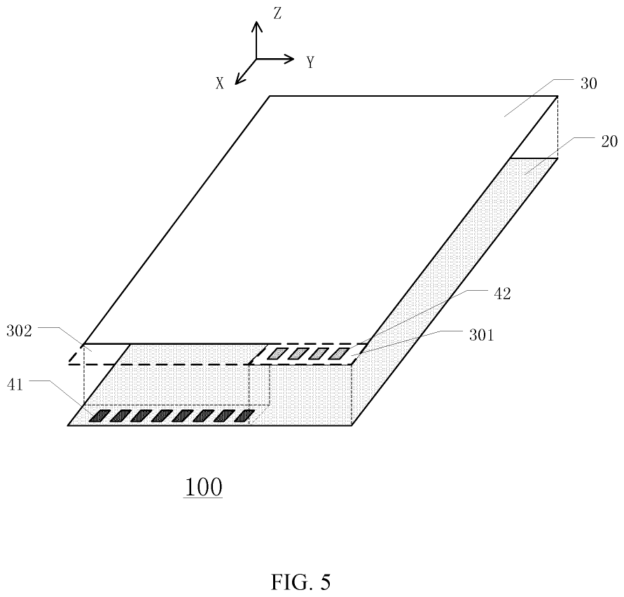

An embodiment of the present disclosure further provides another display panel 100. As shown in FIG. 6, the second substrate 30 includes one protruding portion 301 and two recessed portions 302, and the two recessed portions 302 are at two sides of the protruding portion 310, respectively. That is to say, along the second direction Y, the protruding portion 301 is located between the two recessed portions 302, i.e., one recessed portion 302, one protruding portion 301, and another recessed portion 302 are arranged in sequence.

Further referring to FIG. 6, the first substrate 20 has a first symmetry axis D1 extending along the first direction X. A center point C of the protruding portion 301 in the second direction Y is located on the first symmetry axis D1. That is to say, a half of the protruding portion 301 is located at a left side of the first symmetry axis D1, and the other half of the protruding portion 301 is located at a right side of the first symmetry axis D1. Moreover, the protruding portion 301 is symmetrical about the first symmetry axis D1. The first direction X is perpendicular to the second direction Y.

Further referring to FIG. 6, a distance between the left side recessed portion 302 and the first symmetry axis D1 is equal to a distance between the right side recessed portion 302 and the first symmetry axis D1, and the first binding pins 41 are symmetrically arranged about the first symmetry axis D1, i.e., the binding pins 41 at the left side of the first symmetry axis D1 are arranged symmetrically to the first binding pins 41 at the right side of the first symmetry axis D1. In other words, on the display panel 100, there exists two first binding pins that are equally distanced from the first symmetry axis D1 and are at two side of the first symmetry axis D1, respectively.

In the display panel 100 provided by the embodiment, the protruding portion 301 is positioned between the two recessed portions 302 and the first binding pins 41 are arranged symmetrically about the first symmetry axis D1 in such a manner that the wirings connected to the first binding pins 41 at both the left and right sides of the first symmetry axis D1 have more uniform lengths, so that electrical signal losses caused by difference between lengths of the wirings of the display panel 100 can be more uniform, thereby reducing the process design difficulty of the display panel 100 while improving uniformity of the display panel 100 of the present disclosure.

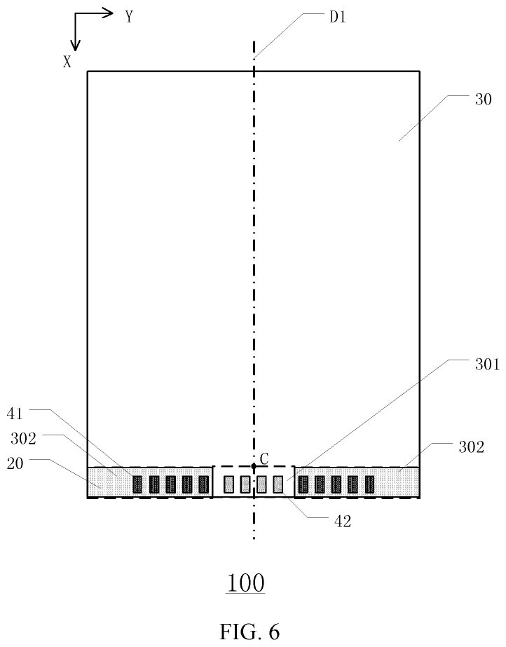

An embodiment of the present disclosure further provides a display panel 100. As shown in FIG. 7, the second substrate 30 includes one protruding portion 301 and one recessed portion 302. The protruding portion 301 has a length M1 in the second direction Y smaller than a length M2 of the recessed portion 302 in the second direction Y. The protruding portion 301 is located at one side of the first symmetry axis D1, and the recessed portion 302 extends across the first symmetry axis D1 to be located at both sides of the first symmetry axis D1. That is, the protruding portion 301 is designed to be close to a corner of the second substrate 30.

Further referring to FIG. 7, a sum of the length M1 of the protruding portion 301 of the second substrate 30 in the second direction Y and the length M2 of the recessed portion 302 of the second substrate 30 in the second direction Y is equal to a length M3 of the first substrate 20 in the second direction Y. That is, the length of the second substrate 30 in the second direction Y is equal to the length of the first substrate 20 in the second direction Y. The entire recessed portion 302 and the entire protruding portion 301 of the second substrate 30 has a total length in second direction Y that is equal to the length of the first substrate 20 in the second direction Y.

Further referring to FIG. 7, the first substrate 20 has a first symmetry axis D1 extending the first direction X, where the first direction X is perpendicular to the second direction Y. The protruding portion 301 of the second substrate 30 is completely located at one side of the first symmetry axis D1. That is, the protruding portion 301 of the second substrate 30 only occupies a length smaller than ½ of the length of the first substrate 20 in the second direction Y. The first binding pins 41 are symmetrically arranged about the first symmetry axis D1, i.e., the first binding pins 41 are located at two sides of the first symmetry axis D1 in equal quantities. The first binding pins 41 at the left side of the first symmetry axis D1 are arranged symmetrically to the first binding pins 41 at the right side of the first symmetry axis D1. On the display panel 100, there are two first binding pins 41 that are equally distanced from the first symmetry axis D1 and are at the two sides of the first symmetry axis D1.

In the display panel 100 provided by this embodiment, the protruding portion 301 is arranged at a corner of the second substrate 30 and is located completely at one side of the first symmetry axis D1. Thus, the first binding pins 41 are not separated into two groups by the second binding pins 42, and the second substrate 30 and the first substrate 20 can transmit signals independent from each other. Moreover, in the case of arranging the protruding portion 301 at one corner of the second substrate 30 but still maintaining symmetrical arrangement of the first binding pins on the first substrate 20 about the first symmetry axis D1, the wirings connected to the first binding pins 41 at both the left and right sides of the first symmetry axis D1 have more uniform lengths, such that the electrical signal losses caused by difference between lengths of the wirings of the display panel 100 can be more uniform, thereby reducing the process design difficulty of the display panel 100 while improving uniformity of the display panel 100 of the present disclosure.

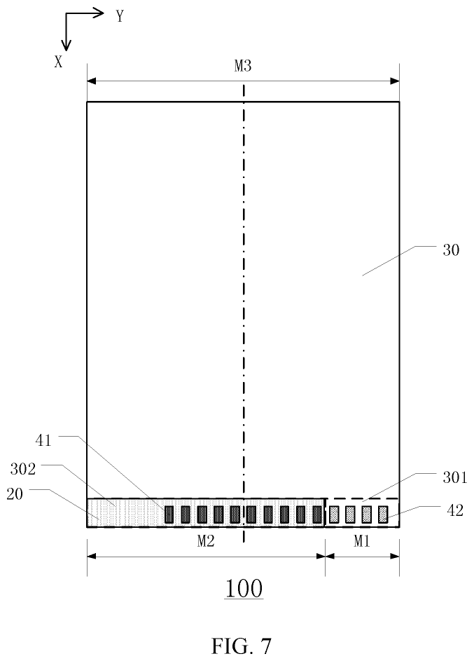

An embodiment of the present disclosure further provides a display panel 100. As shown in FIG. 8, the second substrate 30 includes one protruding portion 301 and one recessed portion 302. The protruding portion 301 has a length M1 in the second direction Y smaller than a length M2 of the recessed portion 302 in the second direction Y. The protruding portion 301 is located at one side of the first symmetry axis D1, and the recessed portion 302 extend across the first symmetry axis D1 and is located at both sides of the first symmetry axis D1, i.e., it is designed that the protruding portion 301 is located close to one corner of the second substrate 30. The first symmetry axis D1 extends along the first direction X, and the first direction X is perpendicular to the second direction Y. The protruding portion 301 of the second substrate 30 is completely located at one side of the first symmetry axis D1. In other words, the protruding portion 301 of the second substrate 30 only occupies a length less than ½ of the length of the first substrate 20 in the second direction Y.

Further referring to FIG. 8, the first binding pins 41 at one side of the first symmetry axis D1 are different in quantity from the first binding pins 41 at the other side of the first symmetry axis D1, i.e., the first binding pins 41 are non-symmetrically arranged about the first symmetry axis D1. FIG. 8 shows a situation in which the number of first binding pins 41 at the left side of the first symmetry axis D1 is greater than the number of first binding pins 41 at the right side of the first symmetry axis D1. This is because the protruding portion 301 of the second substrate 30 occupies a part of space at the right side of the first symmetry axis D1. In addition, the first binding pins 41 are symmetrically arranged at two sides of a second symmetry axis D2 of the recessed portion 302 of the second substrate 30, i.e., the first binding pins 41 are arranged at the two sides of the second symmetry axis D2 in equal quantities. In other words, the first binding pins 41 at the left side of the second symmetry axis D2 are arranged symmetrically to the first binding pins 41 at the right side of the second symmetry axis D2. On the display panel 100, there are two first binding pins 41 that are equally distanced from the second symmetry axis D2 and are at the two sides of the second symmetry axis D2, respectively.

In the display panel 100 of this embodiment, the protruding portion 301 is arranged at one corner of the second substrate 30 and is completely at one side of the first symmetry axis D1 in such a manner that the first binding pins 41 are not separated into two groups by the second binding pins 42, and then the second substrate 30 and the first substrate 20 can transmit signal independent from each other. Moreover, in the case that the protruding portion 301 occupies a part of space of the first substrate 20, the first binding pins 41 are arranged non-symmetrically about the first symmetry axis D1, thereby effectively utilizing an overlapping space between the first substrate 20 and the protruding portion 301, and further reducing the width of the border of the display panel 100 of the present disclosure.

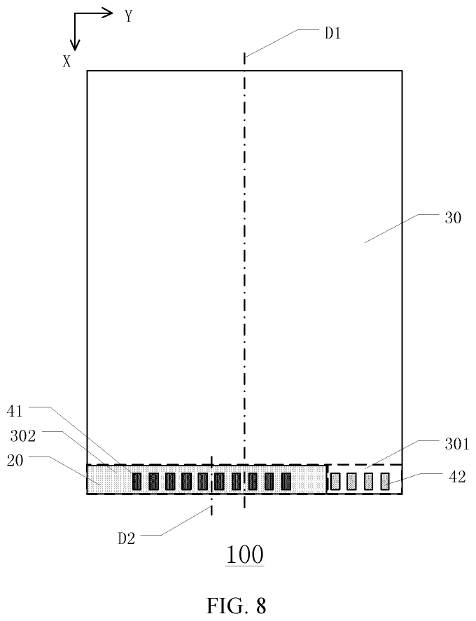

It should be noted that FIGS. 1-8 show situations in which the protruding portion 301 and the recessed portion 302 of the second substrate 30 are located at a lower edge (viewed from the drawings)/short edge of the second substrate 30. In some other embodiments of the present disclosure, the protruding portion 301 and the recessed portion 302 of the second substrate 30 can also be located at a side edge/upper edge of the second substrate 30 or a long edge of the display panel 100, being at only one edge or at more than one edge. FIG. 9 shown a situation in which the protruding portion 301 and recessed portion 302 of the second substrate 30 of display panel 100 are located at a side edge.

As shown in FIG. 9, the display panel 100 include a first substrate 20 and a second substrate 30, and the second substrate 30 includes a protruding portion 301 and recessed portion 302. The first substrate 20 includes a plurality of first binding pins 41, and the second substrate 30 includes a plurality of second binding pins 42. The second binding pins 42 are located at the protruding portion of the second substrate 30, and the recessed portion 302 of the second substrate 30 exposes the first binding pins 41. The protruding portion 301 and recessed portion 302 of the second substrate 30 are located at a side edge of the second substrate 30, i.e., at a long edge of the second substrate 30.

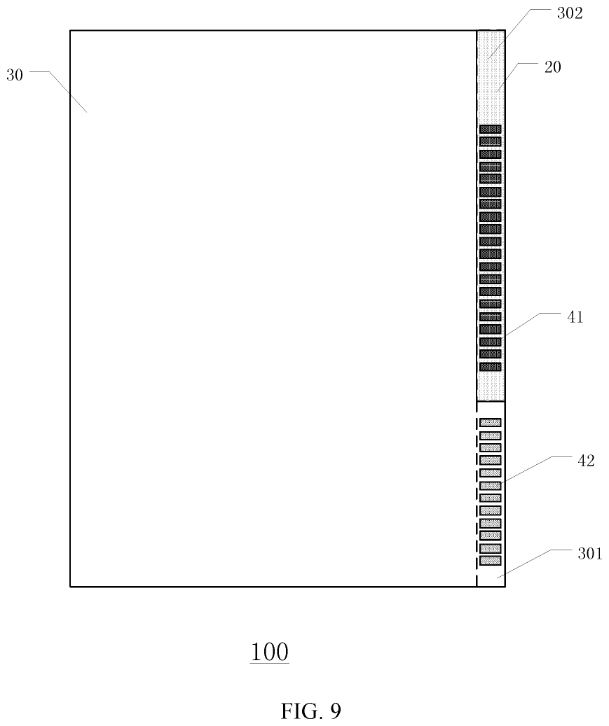

An embodiment of the present disclosure further provides a display panel 100. As shown in FIG. 10, the display panel 100 further includes a first flexible circuit board 51 and a second flexible circuit board 52. The first binding pins 41 are electrically connected to the first flexible circuit board 51, and the second binding pins 42 are electrically connected to the second flexible circuit board 52. The first flexible circuit board 51 includes a plurality of binding pins (not shown), the binding pins (not shown) of the first flexible circuit board 51 are bound to the first binding pins 41 by press fit, so that the first flexible circuit board 51 is electrically connected to the first binding pins 41 so as to provide signals for the first binding pins 41. The second flexible circuit board 52 includes a plurality of binding pins (not shown), the binding pins of the second flexible circuit board 52 are bound to the second binding pins 42 by press fit, so that the second flexible circuit board 52 is electrically connected to the second binding pins 42 to provide signals for the second binding pins 42.

Further referring to FIG. 10, the first flexible circuit board 51 includes a first chip 61 and a plurality of first lead lines 71, and the first chip 61 is electrically connected to the first binding pins 41 by the first lead lines 71. The second flexible circuit board 52 includes a second chip 62 and a plurality of second lead lines 72, and the second chip 62 is electrically connected to the second binding pins 42 by the second lead lines 72. The first lead lines 71 electrically connect the binding pins (not shown) of the first flexible circuit board 51 to the first chip 61, such that the first chip 61 located on the first flexible circuit board 51 is electrically connected to the first binding pins 41 by the first lead lines 71, and then the first chip 61 can provide signals for the first binding pins 41. The second lead lines 72 electrically connect the binding pins of the second flexible circuit board 52 with the second chip 62, such that the second chip 62 located on the second flexible circuit board 52 is electrically connected to the second binding pins 42 by the second lead lines 72, and then the second chip 62 can provide signals for the second binding pins 42. No chip is provided on the first substrate 20 or the second substrate 30.

In the display panel 100 of this embodiment, there includes independent first flexible circuit board 51 and second flexible circuit board 52, and the first chip 61 and second chip 62 located respectively on the first flexible circuit board 51 and second flexible circuit board 52, i.e., a configuration with double flexible circuit boards and double chips allows electric signals to be independently supplied to the first substrate 20 and the second substrate 30, and binding thereof does not affect each other, and the configuration is simpler, thereby improving the reliability of the display panel 100. Besides, no chip is provided on the first substrate 20 or the second substrate 30, the first chip 61 is arranged on the first flexible circuit board 51, and the second chip 62 is arranged on the second flexible circuit board 52, in such a manner that the border of the display panel 100 is further reduced, and thus the display area occupation ratio in the display panel 100 is further increased.

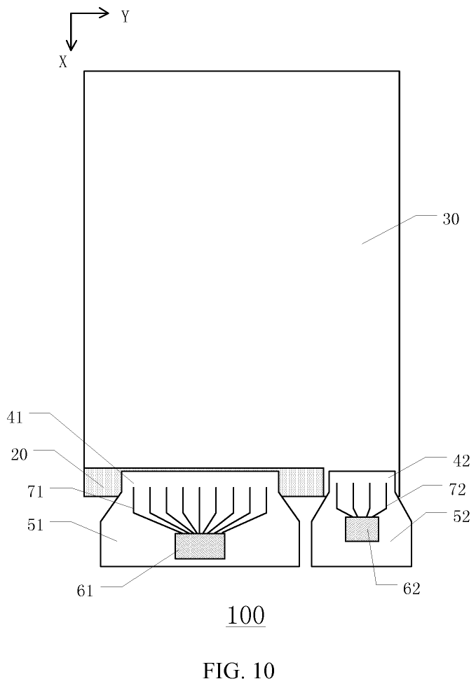

An embodiment of the present disclosure further provides a display panel 100. As shown in FIG. 11, the display panel 100 further includes a first flexible circuit board 51 and a second flexible circuit board 52. The first flexible circuit board 51 is electrically connected to the first binding pins 41, and the second flexible circuit board 52 is electrically connected to the second binding pins 42. The first flexible circuit board 51 includes a plurality of binding pins (not shown), binding pins (not shown) of the first flexible circuit board 51 are bound to the first binding pins 41 by press fit, and thus the first flexible circuit board 51 is electrically connected to the first binding pins 41 and provides electric signals for the first binding pins 41. The second flexible circuit board 52 includes a plurality of binding pins (not shown), the binding pins (not shown) of the second flexible circuit board 52 are bound to the second binding pins 42 by press fit, and thus the second flexible circuit board 52 is electrically connected to the second binding pins 42 and provides electric signals for the second binding pins 42.

Further referring to FIG. 11, the first flexible circuit board 51 includes a first chip 61 and first lead lines 71, and the first chip 61 is electrically connected to the first binding pins 41 by the first lead lines 71. The second flexible circuit board 52 includes second lead lines 72 and an interface 73, and the interface 73 is electrically connected to the second lead lines 72. The second flexible circuit board 52 is electrically connected to the first flexible circuit board 51 by the interface 73. The first chip 61 is electrically connected to the second binding pins 42 by the interface 73 and the second lead lines 72.

In the display panel 100 provided in this embodiment, there includes the first flexible circuit board 51, the second flexible circuit board 52 independent from the first flexible circuit board 51, and the first chip 61 only located on the first flexible circuit board 51, i.e., adopting a configuration with double flexible circuit boards and a single chip so that binding of the first substrate 20 and binding of the second substrate 30 does not affect each other, thereby facilitating signal supply. Use of a single chip can further reduce cost of the display panel 100 and improve user satisfaction. In addition, no chip is provided on the first substrate 20 or the second substrate 30, and a first chip 61 is arranged on the first flexible circuit board 51 and electrically connects the second flexible circuit board 52 to the first flexible circuit board 51, thereby further reducing the width of the border of the display panel 100, and improving a display area ratio in the display panel 100.

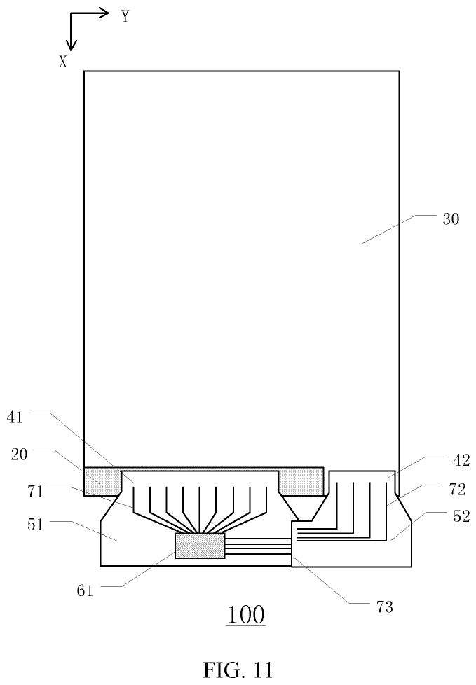

An embodiment of the present disclosure further provides a display panel 100. A shown in FIG. 12, the display panel 100 further includes a first flexible circuit board 51. The first flexible circuit board includes a first connecting portion 81 and a second connecting portion 82. The first connecting portion 81 includes a plurality of connecting pins (not shown), and the first connecting portion 81 is electrically connected to the first binding pins 41 by the connecting pins (not shown). The second connecting portion 82 includes a plurality of connecting pins (not shown), and the second connecting portion is electrically connected to second binding pins 42 by the connecting pins (not shown). That is, the display panel 100 adopts only one first flexible circuit board 51 bound to both the first binding pins 41 and the second binding pins 42.

Further referring to FIG. 12, the first flexible circuit board 51 further includes a first chip 61, first lead lines 71, and second lead lines 72. The first lead lines 71 extend to the first connecting portion 81 and are electrically connected to the connecting pins (not shown) of the first connecting portion 81, such that the first connecting portion 81 is electrically connected to the first chip 61 by the first lead lines 71 and then the first chip 61 can provide signals for the first binding pins 41. The second lead lines 72 extend to the second connecting portion 82 and are electrically connected to the connecting pins (not shown) of the second connecting portion 82, such that the second connecting portion 82 is electrically connected to first chip 61 by the second lead lines 72, and then the first chip 61 can provide signals for the second binding pins 42. That is, the display panel 100 adopts only one first flexible circuit board 51 and only one first chip 61 for binding and providing signals.

In the display panel 100 provided in this embodiment, there includes only one first flexible circuit board 51 and one first chip 61 only located on the first flexible circuit board 51, i.e., adopting a configuration with a single flexible circuit board and a single chip in such a manner that the first substrate 20 and the second substrate 30 are bound to a same flexible circuit board, thereby facilitating signal supply. Use of a single chip and a single flexible circuit board can further reduce the cost of the display panel 100, simplify the manufacturing process, and improve user's satisfaction. In addition, no chip is provided on the first substrate 20 or the second substrate 30, and the first chip 61 is provided on the first flexible circuit board 51 and provides signals for both the first binding pins 41 and second binding pins 42, thereby further reducing the width of the border of the display panel 100 and improving the display area ratio in the display panel 100.

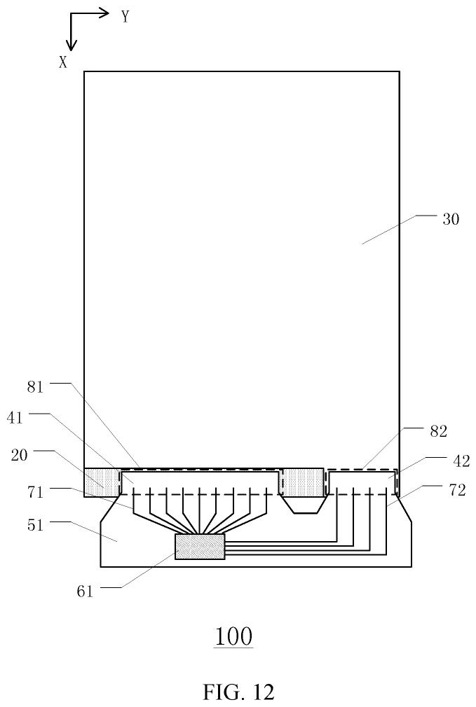

An embodiment of the present disclosure further provides display panel 100. As shown in FIG. 13, the display panel 100 further includes a first flexible circuit board 51. The first flexible circuit board includes a first connecting portion 81 and a second connecting portion 82. The first connecting portion 81 includes a plurality of connecting pins (not shown), and the first connecting portion 81 is electrically connected to the first binding pins 41 by the connecting pins (not shown). The second connecting portion 82 includes a plurality of connecting pins (not shown), and the second connecting portion is electrically connected to second binding pins 42 by the connecting pins (not shown). That is, the display panel 100 adopts only one first flexible circuit board 51 for binding to both the first binding pins 41 and second binding pins 42.

Further referring to FIG. 13, the first flexible circuit board 51 further includes a first chip 61, a second chip 62, first lead lines 71, and second lead lines 72. The first lead lines 71 extend to the first connecting portion 81 and are electrically connected to the connecting pins (not shown) of the first connecting portion 81, such that the first connecting portion 81 is electrically connected to the first chip 61 by the first lead lines 71, and then the first chip 61 can provide signals for the first binding pins 41. The second lead lines 72 extend to the second connecting portion 82 and are electrically connected to the connecting pins (not shown) of the second connecting portion 82, such that the second connecting portion 82 is electrically connected to the second chip 62 by the second lead lines 72, and then the second chip 62 can provide signals for the second binding pins 42. That is, the display panel 100 adopts one first flexible circuit board 51 and two chips (a first chip 61 and a second chip) for binding and providing signals. That is, the display panel 100 adopts one flexible circuit board for binding, and the one flexible circuit board is provided with two chips, and these two chips provide signals for the first binding pins 41 and the second binding pins 42, respectively.

In the display panel 100 provided in this embodiment, there includes only one first flexible circuit board 51 and two chips (the first chip 61 and the second chip 62) located on the first flexible circuit board 51, i.e., adopting a configuration with a single flexible circuit board and two chips, thereby eliminating the binding process of the substrates, simplifying the manufacturing process, and improving user's satisfaction. In addition, no chip is provided on the first substrate 20 or the second substrate 30, the first chip 61 is provided on the first flexible circuit board 51, and the second chip 62 is also provided on the first flexible circuit board 51, thereby further reducing the width of the border of the display panel 100, and improving the display area ratio in the display panel 100.

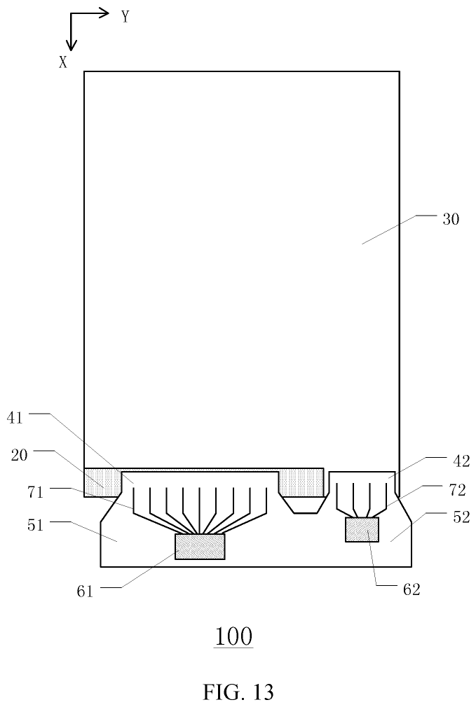

An embodiment of the present disclosure further provides display panel 100. As shown in FIG. 14, the display panel 100 includes a plurality of gate lines G located on the first substrate 20, a plurality of data lines D insulated from and intersecting with the plurality of gate lines G, and a plurality of pixel units P. That is, the first substrate 20 is an array substrate, and an electronic elements of the first substrate 20 can drive the display panel 100 to display. It should be noted that, FIG. 14 only shows an array arrangement pattern of the first substrate 20, and in some other embodiments of the present disclosure, gate lines G, data lines D, and pixel units P of the first substrate 20 can also be arranged in other patterns. For example, the gate lines G are straight lines and the data lines D are polygonal lines in such a manner that the pixel units P are arranged in a dual-domain manner. The pixel units P can be in parallelogram shapes, or irregular polygon shapes with inflection points. The pixel units P can be arranged in a triangle shape, or a diamond shape, etc. The data lines D are electrically connected to the first binding pins 41.

Further referring to FIG. 14, the display panel 100 further includes a plurality of first touch units 92 and a plurality of second touch units 94 on the second substrate 30, a plurality of first touch lead lines 96, and a plurality of second touch lead lines 98. It should be noted that, FIG. 14 only shows one touch mode of the second substrate 30, the touch units include the first touch units 92 and the second touch units 94, and the first touch units 92 and the second touch units 94 form mutual capacitors for detecting a touch position. The first touch units 92 are arranged in a strip shape, and are electrically connected to the first touch lead lines 96, and the first touch lead lines 96 are also electrically connected to the second binding pins 42. The second touch units 94 are spaced from one another by the first touch units 92, each of the second touch lead lines 98 are electrically connected to a number of second touch units 94, and the second touch lead lines 98 are electrically connected to the second binding pins 42. A sum of the number of the first touch lead lines 96 and the number of the second touch lead lines 98 is smaller than the number of the data lines D.

In the display panel 100 provided in this embodiment, the first substrate 20 is set to be an array substrate, and the second substrate 30 is set to be a touch substrate. In this manner, the first touch lead lines 96 and second touch lead lines 98 with small quantities are located on the second substrate 30, thereby reducing a width of the protruding portion 30, facilitating binding of the data lines D with a large quantity on the first substrate 20, reducing design difficulty of the display panel 100, and increasing reliability of the display panel 100.

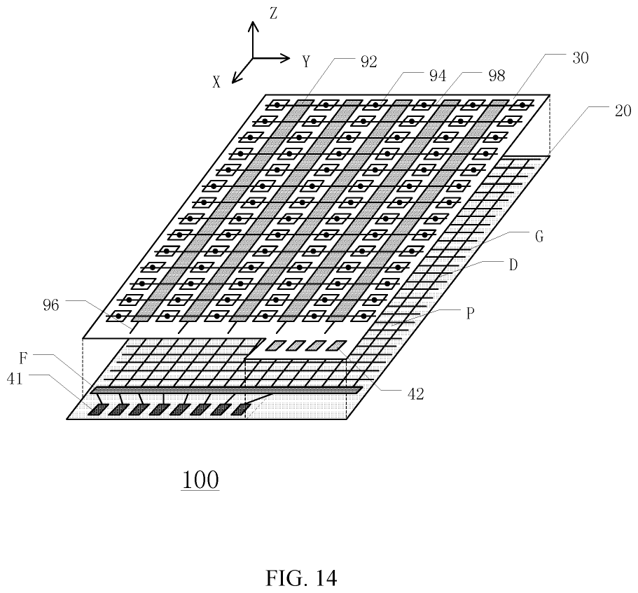

An embodiment of the present disclosure further provides a display panel 100. As shown in FIG. 15, the display panel 100 is an organic light-emitting display panel. The display panel 100 includes a first substrate 20 and a second substrate 30. A protection layer, a semiconductor layer, a first insulation layer, a gate metal layer, a second insulation layer, a capacitor metal layer, a third insulation layer, a source-drain metal layer, a fourth insulation layer, and a pixel definition layer are stacked on the first substrate. The gate electrode of the transistor is located in the gate metal layer, and the source-drain electrodes of the transistor are located in the source-drain metal layer. The first electrode plate of the capacitor component is located in the gate metal layer, and the second electrode plate of the capacitor component is located in the capacitor metal layer. The pixel definition layer has an aperture, and the light-emitting material 56 is located in the aperture. Each of the pixel units P of the first substrate 20 includes a light-emitting element, and the light-emitting element includes an anode 55, a light-emitting material 56, and a cathode 57.

Further referring to FIG. 15, the second substrate 30 includes first touch units 92. The second substrate 30 and the first substrate 20 have supporting pillars, and the second substrate 30 and the first substrate 20 are encapsulated into the display panel 100 by film encapsulation or laser melt encapsulation. The first substrate 20 is an encapsulation layer structure composed of an inorganic layer, an organic layer, and another inorganic layer in sequence. The first touch units 92 are then formed on a surface of an outermost layer of the first substrate 20. In the laser melt encapsulation process, a glass material is placed between the first substrate 20 and the second substrate 30, and is melt by laser so as to attach and seal the first substrate 20 and the second substrate 30 together.

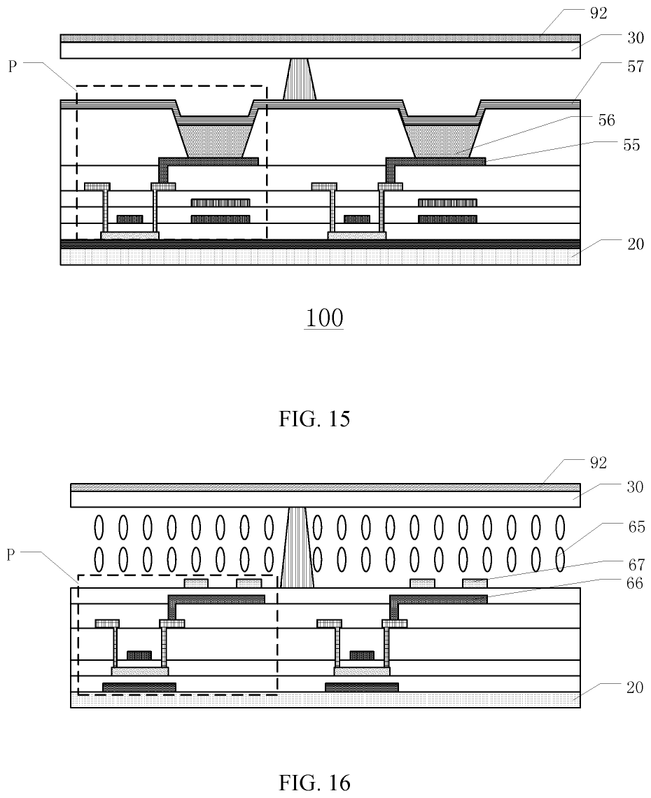

An embodiment of the present disclosure further provides display panel 100. As shown in FIG. 16, the display panel 100 includes a first substrate 20, a second substrate 30, liquid crystals 65 between the first substrate 20 and the second substrate 30. The first substrate 20 includes a light shielding metal layer, a first insulation layer, a semiconductor layer, a second insulation layer, a gate metal layer, a third insulation layer, a source-drain metal layer, a fourth insulation layer, a pixel electrode, a fifth insulation layer, and a common electrode which are stacked in sequence. Each pixel unit P includes a pixel electrode 66 and a common electrode 67 positioned opposite to the pixel electrode 66. It should be noted that, FIG. 16 only shows one arrangement manner for the first substrate 20, and in some other embodiments of the present disclosure, there could be no light shielding metal layer on the first substrate 20 and the gate metal layer could be located between the semiconductor layer and the first substrate 20. The common electrode on the first substrate 20 can also be located between the first substrate 20 and the pixel electrode, i.e., adopting a mid-com structure.

Further referring to FIG. 16, the second substrate 30 includes first touch units 92. The second substrate 30 and the first substrate 20 have supporting pillars, and the second substrate 30 and the first substrate 20 are attached together by ultraviolet curing. A curing adhesive is placed between the first substrate 20 and the second substrate 30, and is then cured by ultraviolent light irradiation to attach and seal the first substrate 20 and the second substrate 30 together.

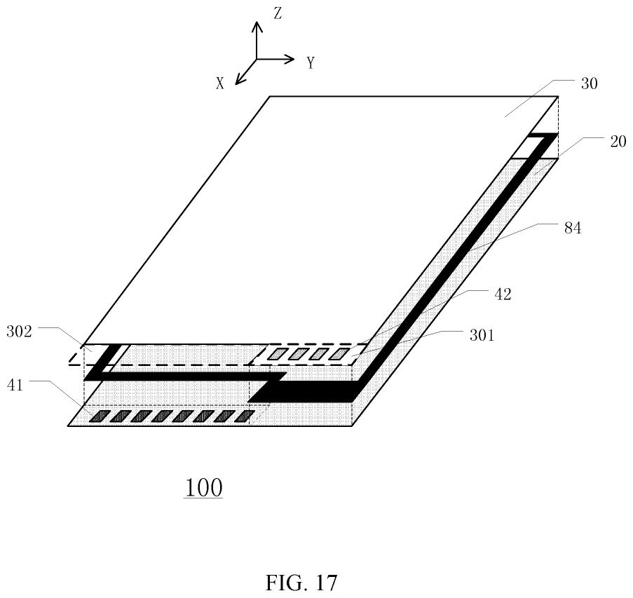

An embodiment of the present disclosure further provides a display panel 100. As shown in FIG. 17, the display panel 100 includes an encapsulation component 84 located between the first substrate 20 and the second substrate 30. The protruding portion 301 overlaps the encapsulation component 84. Further, a projection of the protruding portion 301 in the direction perpendicular to the display panel (third direction Z) is completely located within the encapsulation component 84. That is, the encapsulation component 84 is completely between the whole protruding portion 301 and the first substrate 20.

When the display panel 100 is an organic light-emitting display panel, the encapsulation component 84 is a glass material or a barrier wall. If the laser melt encapsulating process is adopted, the encapsulation component 84 is a glass material placed between the first substrate 20 and the second substrate 30. If the film encapsulating process is adopted, the encapsulation component 84 and the second substrate 30 are integrally formed, i.e., a barrier wall is formed at protruding portion 301 for the first substrate 20. When the display panel 100 is a liquid crystal display panel, the encapsulation component 84 is a curing adhesive between the first substrate 20 and the second substrate 30.

In the display panel 100 provided in this embodiment, the encapsulation component 84 overlaps the protruding portion 301 of the second substrate 30, and acts to support and protect the protruding portion 301 during binding of the second binding pins 42, such that the protruding portion 301 is not easily broken, thereby increasing reliability of the display panel 100 provided in this embodiment.

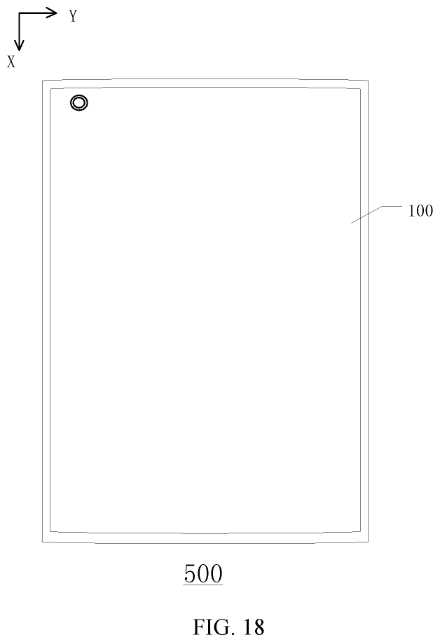

An embodiment of the present disclosure further provides a display device 500. As shown in FIG. 18, the display device 500 includes the display panel 100 according any of the embodiments of the present disclosure. It should be noted that, FIG. 18 only shows an example of the display device 500, and the shape and application of the display device 500 are not limited to those shown in FIG. 18. In some other embodiments of the present disclosure, the display device 500 can be shaped in a rectangle or not shaped in a rectangle. The display device 500 can has no border at all, or has at least one border.

In the display device 500 provided in this embodiment, the included display panel 100 has an second substrate 30 provided with the protruding portion 301 and the recessed portion 302, the second binding pins 42 are provided at the protruding portion 301, and the first binding pins 41 are exposed at the recessed portion 302. In this way, the first binding pins 41 partially overlap the second binding pins 42 in the second direction Y of the display device 500, i.e., a projection of the first binding pins 41 in the second direction Y overlaps a projection of the second binding pins 42 in the second direction Y, thereby reducing the width of the display device 500 in the first direction X. In the display device 500 of this embodiment, the first binding pins 41 and the second binding pins 42 avoid from each other in the direction perpendicular to the display panel (third direction Z), but overlap each other in the second direction Y such that a total width of the binding region of the display device 500 is reduced, thereby realizing a narrow border and increasing the display area occupation ratio.

The device embodiment described above is merely illustrative, the units illustrated as separate components may or may not be physically separated, and the components shown as units may or may not be physical units, i.e., they may be located in one place, or may be distributed to at least two network units. Some or all of the modules may be selected according to actual needs to achieve the purpose of the solution of the embodiment.

It should be noted that the above embodiments are merely used to illustrate the technical solutions of the present disclosure, and are not intended for limiting; although the present disclosure has been described in detail with reference to the foregoing embodiments, those of ordinary skill in the art can still modify the technical solutions described in the foregoing embodiments may, or equivalently replace some or all of the technical features; and the obtained technical solution with the modifications or replacements do not deviate from the essence of the technical solutions of the embodiments of the present disclosure.

What is claimed is:

1. A display panel, comprising:
a first substrate comprising a plurality of first binding pins; and
a second substrate arranged opposite to the first substrate, the second substrate comprising a plurality of second binding pins, at least one protruding portion, and at least one recessed portion,
wherein the plurality of second binding pins is located on the at least one protruding portion of the second substrate, and the plurality of first binding pins of the first substrate is exposed from the at least one recessed portion of the second substrate.

2. The display panel according to claim 1, wherein a part of a first edge of the first substrate overlaps with a first edge of the protruding portion of the second substrate.

3. The display panel according to claim 1, wherein the recessed portion of the second substrate has a length in a first direction greater than or equal to a length of each of the plurality of first binding pins in the first direction.

4. The display panel according to claim 1, wherein the second substrate comprises one protruding portion and two recessed portions, and the two recessed portions are arranged at two sides of the one protruding portion, respectively;
the first substrate has a first symmetry axis extending along a first direction;
in a second direction, the protruding portion has a center point located on the first symmetry axis; and
the first direction is perpendicular to the second direction.

5. The display panel according to claim 4, wherein the plurality of first binding pins is symmetrically arranged with respect to the first symmetry axis.

6. The display panel according to claim 1, wherein the second substrate comprises at least one protruding portion and at least one recessed portion; and
the one protruding portion has a length in a second direction smaller than a length of the one recessed portion in the second direction.

7. The display panel according to claim 6, wherein a sum of the length of the one protruding portion of the second substrate in the second direction and the length of the one recessed portion of the second substrate in the second direction is equal to a length of the first substrate in the second direction.

8. The display panel according to claim 7, wherein the first substrate has a first symmetry axis extending along a first direction, the first direction being perpendicular to the second direction; and
the one protruding portion of the second substrate is located at one side of the first symmetry axis.

9. The display panel according to claim 8, wherein the plurality of first binding pins is symmetrically arranged with respect to the first symmetry axis.

10. The display panel according to claim 8, wherein different quantities of the plurality of first binding pins are distributed at either side of the first symmetry axis.

11. The display panel according to claim 1, further comprising a first flexible circuit board and a second flexible circuit board,
wherein the plurality of first binding pins is electrically connected to the first flexible circuit board; and
the plurality of second binding pins is electrically connected to the second flexible circuit board.

12. The display panel according to claim 11, wherein the first flexible circuit board comprises a first chip and a plurality of first lead lines, and the first chip is electrically connected to the plurality of first binding pins by the plurality of first lead lines; and
the second flexible circuit board comprises a second chip and a plurality of second lead lines, and the second chip is electrically connected to the plurality of second binding pins by the plurality of second lead lines.

13. The display panel according to claim 11, wherein the first flexible circuit board comprises a first chip and a plurality of first lead lines, and the first chip is electrically connected to the plurality of first binding pins by the plurality of first lead lines;
the second flexible circuit board comprises a plurality of second lead lines, and the second flexible circuit board is electrically connected to the first flexible circuit board; and
the first chip is electrically connected to the plurality of second binding pins by the plurality of second lead lines.

14. The display panel according to claim 1, further comprising a first flexible circuit board,
wherein the first flexible circuit board comprises a first connecting portion and a second connecting portion; and
the first connecting portion is electrically connected to the plurality of first binding pins, and the second connecting portion is electrically connected to the plurality of second binding pins.

15. The display panel according to claim 14, wherein the first flexible circuit board further comprises a first chip, a plurality of first lead lines, and a plurality of second lead lines;
the first connecting portion is electrically connected to the first chip by the plurality of first lead lines; and
the second connecting portion is electrically connected to the first chip by the plurality of second lead lines.

16. The display panel according to claim 14, wherein the first flexible circuit board further comprises a first chip, a second chip, a plurality of first lead lines, and a plurality of second lead lines;
the first connecting portion is electrically connected to the first chip by the plurality of first lead lines; and
the second connecting portion is electrically connected to the second chip by the plurality of second lead lines.

17. The display panel according to claim 1, further comprising:
a plurality of gate lines,
a plurality of data lines intersecting with and insulated from the plurality of gate lines,
a plurality of pixel units;
a plurality of touch units; and
a plurality of touch lead lines,
wherein the plurality of gate lines, the plurality of data lines, and the plurality of pixel units are located on the first substrate,
the plurality of touch units and the plurality of touch lead lines are located on the second substrate, and
the plurality of data lines is electrically connected to the plurality of first binding pins, and the plurality of touch lead lines is electrically connected to the plurality of second binding pins.

18. The display panel according to claim 17, wherein each pixel unit of the plurality of pixel units comprises a light-emitting element, and the light-emitting element comprises an anode, a light-emitting material, and a cathode.

19. The display panel according to claim 17, further comprising liquid crystals arranged between the first substrate and the second substrate, wherein each pixel unit of the plurality of pixel units comprises a pixel electrode and a common electrode arranged opposite to the pixel electrode.

20. The display panel according to claim 1, further comprising an encapsulation component arranged between the first substrate and the second substrate, wherein the at least one protruding portion overlaps with the encapsulation component.

21. A display device, comprising the display panel according to claim 1.
